(19) United States
(12) Patent Application Publication
(10) Pub. No.: US 2024/0304609 A1
(43) Pub. Date: Sep. 12, 2024

(54) MULTIPLE-LAYERED COVER STRUCTURE FOR BEAMSHAPING FOR LIGHT-EMITTING DIODE DEVICES

(71) Applicant: CreeLED, Inc., Durham, NC (US)

(72) Inventors: Ayush Tripathi, Raleigh, NC (US); Robert Wilcox, Rolesville, NC (US); Tucker McFarlane, Cary, NC (US); Nathan Steinmetz, Apex, NC (US); Colin Blakely, Raleigh, NC (US)

(21) Appl. No.: 18/117,630

(22) Filed: Mar. 6, 2023

(51) Int. Cl. H01L 25/16; H01L 33/10; H01L 33/26; H01L 33/50; H01L 33/52

(52) U.S. Cl. CPC H01L 25/167; H01L 33/10; H01L 33/26; H01L 33/502; H01L 33/52

(57) ABSTRACT

Solid-state lighting devices, and more particularly, a multiple-layered cover structure for beamshaping for light-emitting devices such as light-emitting diodes (LEDs) are disclosed. LED devices may include the cover structures that have more than one layer, each with different index of refractions and/or shapes in order to provide more finely tuned beamshaping than would be possible with a cover structure formed from a single layer of silicone. The cover structure can cover a side and a top of an LED chip and include an inner layer with a first refractive index that covers at least a top of the LED chip, and an outer layer with second refractive index. The cover structure also includes lumiphoric material, either in one of the inner or outer layer, or in a separate layer. The inner and outer layers can be of different shapes to result in an emission with desired characteristics.

### FIELD OF THE DISCLOSURE

The present disclosure relates to solid-state lighting devices, and more particularly to a multiple-layered cover structure for beamshaping for light-emitting diode devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination and automotive applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

Chip covers or cover structures are used in LEDs, which require tight control of the LED emission area. Optical emission properties of chip covers, e.g., beam angle, color over angle, emission pattern, and emission axis in existing chip covers, are primarily determined by the material used in the lens. The cover structures currently used are typically one layer of material, accompanied by a conversion layer of lumiphoric material that can convert the light emitted by an LED chip into generally white light. Various embodiments of current cover structures are shown in FIGS. 1A, 1B, 1C, and 1D. For example, in FIG. 1A, a cover structure 101 can include a single layer 108 along with conversion layer 106 over the top of an LED chip 104 and a substrate 102. There are a number of other convention variations as shown in FIG. 1B where a reflector layer 110 is provided on either side of the LED chip 104, and in FIG. 1C, where the reflector layer 110 is provided on the sides of the LED chip 104, with the conversion layer 106 above the reflector layer 110 and the LED chip 104. In FIG. 1D, the cover structure can include a conversion layer 106 just over the top of the LED chip 104 without covering the sidewalls 114 of the LED chip 104, and the layer 108 of the cover structure 101 can cover the sidewalls 114.

In application, LEDs are typically coupled into a secondary optic to achieve the directionality or emission pattern for the final luminaire. This results in several inefficiencies, such as light loss due to imperfect coupling to the secondary optic and large luminaire designs in both the LED (with a heatsink) and secondary optic.

The art continues to seek improved LEDs and solid-state lighting devices having desirable illumination characteristics capable of overcoming challenges associated with conventional lighting devices.

### SUMMARY

The present disclosure relates to solid-state lighting devices, and more particularly to a multiple-layered cover structure for beamshaping for light-emitting devices such as light-emitting diodes (LEDs). LED devices may include the cover structures that have more than one layer, each with different index of refractions and/or shapes in order to provide more finely tuned beamshaping than would be possible with a cover structure formed from a single layer of silicone. The cover structure can cover a side and a top of an LED chip and include an inner layer with a first refractive index that covers at least a top of the LED chip, and an outer layer with second refractive index. The cover structure also includes lumiphoric material, either in one of the inner or outer layer, or in a separate layer to provide a conversion layer. The inner and outer layers can include different shapes to provide more finally tuned beamshaping and result in an emission with desired characteristics (direction, color over angle, etc.).

In an embodiment, an LED device can include a substrate and an LED chip on a top surface of the substrate. The LED device can also include a cover structure in contact with the substrate that covers a top surface and a side of the LED chip where the cover structure includes an inner layer with a first refractive index, wherein the inner layer covers at least the top surface of the LED chip, an outer layer with a second refractive index different than the first refractive index, wherein the inner layer is between the LED chip and the outer layer, and a lumiphoric material.

In an embodiment, the inner layer and the outer layer comprise one or more of a silicone material, glass, or a light-transmitting ceramic material.

In an embodiment, a difference between the first refractive index and the second refractive index is at least 0.05.

In an embodiment, the inner layer and the outer layer are different shapes.

In an embodiment, the lumiphoric material forms a conversion layer between the LED chip and the inner layer and outer layer of the cover structure.

In an embodiment, the lumiphoric material forms a conversion layer between the inner layer and the outer layer.

In an embodiment, the lumiphoric material is embedded in at least one of the inner layer or outer layer.

In an embodiment, the inner layer and the outer layer are different shapes.

In an embodiment, the LED device can further include a diffuser layer between the inner layer and the outer layer.

In an embodiment, the LED device can further include a reflector layer around a sidewall of the LED chip.

In an embodiment, the lumiphoric material forms a conversion layer between the sidewall of the LED chip and the reflector layer.

In an embodiment, the reflector layer is in contact with the sidewall of the LED chip.

In an embodiment, the lumiphoric material forms a conversion layer over the top surface of the LED chip and the reflector layer.

In an embodiment, the inner layer and the outer layer are injection molded.

In an embodiment, the inner layer covers the side of the LED chip.

In another embodiment, another LED device can be provided that includes a substrate and an LED chip on a top surface of the substrate. The LED device can also include a cover structure in contact with the substrate that covers a top surface and a side of the LED chip, the cover structure can include an inner layer with a first refractive index, wherein the inner layer covers at least the top surface of the LED chip, wherein the inner layer comprises a lumiphoric material. The cover structure can also include an outer layer with a second refractive index different than the first refractive index, wherein the inner layer is between the LED chip and the outer layer.

In an embodiment, the inner layer and the outer layer comprise one or more of a silicone material, glass, or a light-transmitting ceramic material.

In an embodiment, a difference between the first refractive index and the second refractive index is at least 0.05.

In an embodiment, the inner layer and the outer layer are different shapes.

In an embodiment, the LED device can further include a diffuser layer between the inner layer and the outer layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a conventional light-emitting diode (LED) device with a single layer cover structure.

FIG. 1B is a cross-sectional view of a conventional LED device with a single layer cover structure and reflector layer.

FIG. 1C is a cross-sectional view of a conventional LED device with a single layer cover structure and reflector layer.

FIG. 1D is a cross-sectional view of a conventional LED device with a single layer cover structure and a wire bond.

FIG. 2 is a cross-sectional view of an LED device with a multiple layered cover structure with layers of different refractive indexes according to aspects disclosed herein.

FIG. 3 is a cross-sectional view of an LED device with a multiple layered cover structure with layers of different refractive indexes and shapes according to aspects disclosed herein.

FIG. 4 is a cross-sectional view of an LED device with a multiple layered cover structure with layers of different refractive indexes and shapes according to aspects disclosed herein.

FIG. 5 is a cross-sectional view of an LED device with a multiple layered cover structure with layers of different refractive indexes and shapes according to aspects disclosed herein.

FIG. 6 is a cross-sectional view of an LED device with a multiple layered cover structure with layers of different refractive indexes and a different arrangement of a conversion layer of lumiphoric material according to aspects disclosed herein.

FIG. 7 is a cross-sectional view of an LED device with a multiple layered cover structure with layers of different refractive indexes and a different arrangement of a conversion layer of lumiphoric material according to aspects disclosed herein.

FIG. 8 is a cross-sectional view of an LED device with a multiple layered cover structure with layers of different refractive indexes and a different arrangement of a conversion layer of lumiphoric material according to aspects disclosed herein.

FIG. 9 is a cross-sectional view of an LED device with a multiple layered cover structure with layers of different refractive indexes and a diffuser layer according to aspects disclosed herein.

FIG. 10 is a cross-sectional view of an LED device with a multiple layered cover structure with layers of different refractive indexes and shapes and a diffuser layer according to aspects disclosed herein.

FIG. 11 is a cross-sectional view of an LED device with a multiple layered cover structure with layers of different refractive indexes and a diffuser layer and a different arrangement of a conversion layer of lumiphoric material according to aspects disclosed herein.

FIG. 12 is a cross-sectional view of an LED device with a multiple layered cover structure with layers of different refractive indexes and a reflector layer according to aspects disclosed herein.

FIG. 13 is a cross-sectional view of an LED device with a multiple layered cover structure with layers of different refractive indexes and a reflector layer and a diffuser layer according to aspects disclosed herein.

FIG. 14 is a cross-sectional view of another LED device with a multiple layered cover structure with layers of different refractive indexes and a reflector layer and a diffuser layer according to aspects disclosed herein.

FIG. 15 is a cross-sectional view of another LED device with a multiple layered cover structure with layers of different refractive indexes and a reflector layer and a diffuser layer according to aspects disclosed herein.

FIG. 16 is a cross-sectional view of an LED device with a multiple layered cover structure with layers of different refractive indexes and embedded lumiphoric material according to aspects disclosed herein.

FIG. 17 is a cross-sectional view of another LED device with a multiple layered cover structure with layers of different refractive indexes and embedded lumiphoric material according to aspects disclosed herein.

FIG. 18 is a cross-sectional view of another LED device with a multiple layered cover structure with layers of different refractive indexes and embedded lumiphoric material according to aspects disclosed herein.

FIG. 19 is a cross-sectional view of another LED device with a multiple layered cover structure with layers of different refractive indexes and embedded lumiphoric material according to aspects disclosed herein.

FIG. 20 is a cross-sectional view of another LED device with a multiple layered cover structure with layers of different refractive indexes and a reflector layer according to aspects disclosed herein.

FIG. 21 is a cross-sectional view of another LED device with a multiple layered cover structure with layers of different refractive indexes and a reflector layer according to aspects disclosed herein.

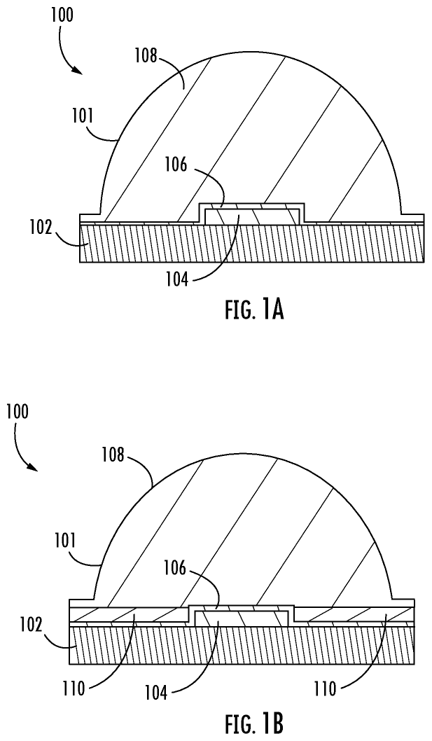

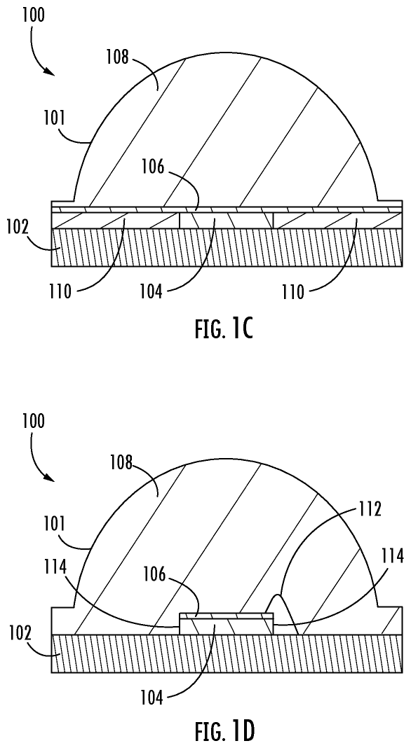

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices, and more particularly to a multiple-layered cover structure for beamshaping for light-emitting devices such as light-emitting diodes (LEDs). LED devices may include the cover structures that have more than one layer, each with different index of refractions and/or shapes in order to provide more finely tuned beamshaping than would be possible with a cover structure formed from a single layer of silicone. The cover structure can cover a side and a top of an LED chip and include an inner layer with a first refractive index that covers at least a top of the LED chip, and an outer layer with second refractive index. The cover structure also includes lumiphoric material, either in one of the inner or outer layer, or in a separate layer to provide a conversion layer to convert the light emitted by the LED chip to generally white light. The inner and outer layers can include different shapes to provide more finally tuned beamshaping and result in a light emission profile with desired characteristics (direction, color over angle, etc.).

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group Ill nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500K to 10,000K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more surfaces of LED chips may be conformally coated with one or more lumiphoric materials, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip is initiated in all directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be arranged for flip-chip mounting on another surface.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

In certain embodiments, the light-altering material includes both light-reflective material and light-absorbing material suspended in a binder. A weight ratio of the light-reflective material to the binder may comprise a range of about 1:1 to about 2:1. A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percent that is in a range of about 10% to about 90% of the total weight of the light-altering material. The light-reflective material may comprise a weight percent that is in a range of about 10% to about 90% of the total weight of the light-altering material. The light-absorbing material may comprise a weight percent that is in a range of about 0% to about 15% of the total weight of the light-altering material.

In further embodiments, the light-absorbing material may comprise a weight percent that is in a range of about greater than 0% to about 15% of the total weight of the light-altering material. In further embodiments, the binder may comprise a weight percent that is in a range of about 25% to about 70% of the total weight of the light-altering material. The light-reflective material may comprise a weight percent that is in a range of about 25% to about 70% of the total weight of the light-altering material. The light-absorbing material may comprise a weight percent that is in a range of about 0% to about 5% of the total weight of the light-altering material. In further embodiments, the light-absorbing material may comprise a weight percent that is in a range of about greater than 0% to about 5% of the total weight of the light-altering material.

In certain applications, LED devices as disclosed herein may be well suited in closely-spaced array applications such automotive lighting, general lighting, and lighting displays. For exterior automotive lighting, multiple LED devices may be arranged under a common lens or optic to provide a single overall emission or emissions that are capable of changing between different emission characteristics. Changing emission characteristics may include toggling between high beam and low beam emissions, adaptively changing emissions, and adjusting correlated color temperatures (CCTs) that correspond with daytime and nighttime running conditions. In general lighting applications, LED devices as disclosed herein may be configured to provide modules, systems, and fixtures that are capable of providing one or more different emission colors or CCT values, such as one or more of warm white (e.g., 2700 Kelvin (K)-3000 K), neutral white (e.g., 3500 K-4500 K), and cool white (5000 K-6500 K). For horticulture lighting applications, LED devices as disclosed herein may be arranged to provide modules, systems, and fixtures that are capable of changing between different emission characteristics that target various growth conditions of different crops.

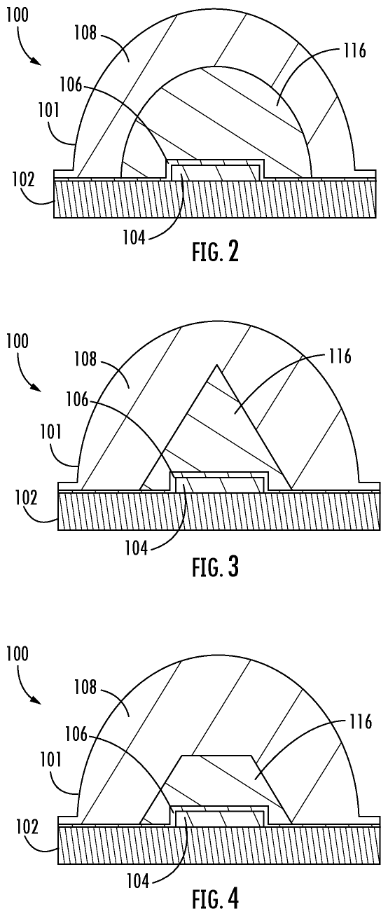

FIG. 2 illustrates a cross-sectional view of an LED device 100 with a multiple layered cover structure 101 with layers of different refractive indexes according to aspects disclosed herein.

In certain embodiments, the LED device 100 may comprise a cover structure 101 that includes an outer layer 108 and an inner layer 116 as well as a conversion layer 106 that comprises lumiphoric material. The outer layer 108 and inner layer 116 can be lenses, that due to their shape and refractive indexes, can redirect light, or change the focal length of the light emitted. The outer layer 108 and the inner layer 116 can comprise materials that are light-transmissive and/or transparent to light emitted by the LED chip 104 and light that is converted by the conversion layer 106. The outer layer 108 and the inner layer 116 may also be textured to improve light extraction or contain materials such as phosphors or scattering particles. The conversion layer 106 may comprise any of the materials as previously described, including one or more phosphors that provide the same or different emission characteristics. In certain embodiments, the outer layer 108 and the inner layer 116 and the conversion layer 106 may be attached to the LED chip 104 and/or substrate 102 on which the LED chip 104 is attached using, for example, a layer of transparent adhesive such as silicone. In other embodiments, the conversion layer 106, inner layer 116, and outer layer 108 may be formed on the LED chip 104 and substrate 102 such as by molding the layers directly onto the substrate 102 and LED chip 104. In an example shown in FIG. 2, the conversion layer 106 is formed between the inner layer 116 and the LED chip 104, thereby protecting the conversion layer 106 from environmental exposure.

The outer layer 108 and the inner layer 116 can have different refractive indexes so as to further beamshape the light and result in light emitted from the LED device 100 with desired characteristics. In an example, the refractive indexes of the inner layer 116 and the outer layer 108 can be between 1.1 and 2. In an embodiment, to achieve the lower refractive indexes, the material that forms the inner layer 116 or outer layer 108 can be emulsified before being cured to create air bubbles within the material which can reduce the bulk refractive index. In an embodiment, the difference between a first refractive index of the outer layer 108 and a second refractive index of the inner layer 116 can be at least 0.05. In an embodiment, the inner layer 116 and the outer layer 108 can each be formed from silicone materials or glass, with different formulations to achieve the different refractive indexes. In an embodiment, one effect of having two layers of the cover structure 101 is that yellow leakage around a perimeter of the LED device 100 can be reduced.

In an embodiment, the inner layer 116 and the outer layer 108 of the cover structure and/or the conversion layer 106 can be attached to the substrate 102 with an adhesive. In other embodiments, the conversion layer 106, inner layer 116, and outer layer 108 may be formed on the LED chip 104 and substrate 102 such as by molding the layers directly onto the substrate 102 and LED chip 104. In an embodiment, the cover structure 101 can be at least in partial contact with the LED chip 104. In other embodiments the cover structure 101 can be separated from the LED chip 104 by an air or vacuum gap.

In an embodiment, the inner layer 116 and the outer layer 108 of the cover structure 101 can each be individually or separately formed, via injection molding, or some other molding technique, and then joined together before being attached or fixed the substrate 102 and LED chip 104. In other embodiments, the conversion layer, inner layer 116 and outer layer 108 can be sequentially attached or fixed to the substrate 102 and LED chip 104.

In FIGS. 3 and 4, the arrangement of the outer layer 108, inner layer 116, and conversion layer 106 of the cover structure 101 with respect to the substrate 102 and LED chip 104 can be similar to the embodiment shown in FIG. 2, except the shape of the inner layer 116 can be different from that of the shape of the outer layer 108. For example, in FIG. 3, the inner layer 116 can be a triangle, while in FIG. 4, the inner layer 116 can be trapezoidal. The various shapes can alter the emission characteristics of the LED device 100. These differences in designs can allow for nontraditional emission where the maximum intensity is not directly above the LED chip 104 at zero degrees of tilt.

In the embodiments shown in FIGS. 2-4, each of components of the cover structure 101 can extend below a top surface of the LED chip 104 and cover and/or surround the sides of the LED chip 104. In the embodiment shown in FIG. 5 however, the inner layer 116 can be fixed to the top of the LED chip 104 but not extend below the top of the LED chip 104 to cover or surround the sides of the LED chip 104. Thus, light emitted from the sides of the LED chip 104 will still pass through the conversion layer 106, but will only pass through one layer (the outer layer 108) of the cover structure 101.

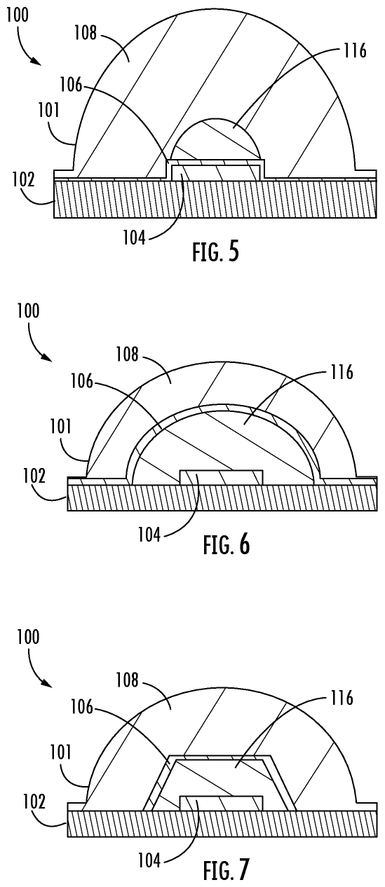

In FIG. 6, the conversion layer 106 can lay between the inner layer 116 and the outer layer 108. The inner layer 116 can be in contact with the top and sides of the LED chip 104, and provide a gap between the LED chip 104 and the conversion layer 106. The gap can be result in an improved color profile of the light emitted by the LED device 100 as the light emitted by the LED chip 104 will be more likely to pass through the conversion layer 106 with a uniform angle (e.g., more perpendicular to the surface of the conversion layer 106) resulting in more light passing through equal distances of conversion layer 106 and a more uniform color conversion.

Similar to the embodiments of FIGS. 4 and 5 relative to FIG. 2, FIGS. 7 and 8 present different embodiments relative to FIG. 6, where the conversion layer 106 is between the inner layer 116 and the outer layer 108, but the inner layer 116 can be of a different shape (e.g., triangular, trapezoidal as shown in FIG. 7, or any other possible shape) or cover just a top surface of the LED chip as in FIG. 8.

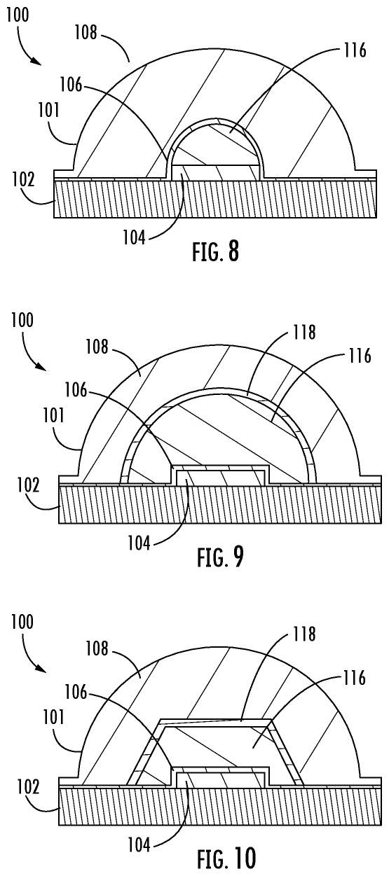

FIG. 9 is a cross-sectional view of an LED device 100 with a multiple layered cover structure 101 with layers of different refractive indexes and a diffuser layer according to aspects disclosed herein. The embodiment in FIG. 9 is similar to the embodiment in FIG. 2, except that in FIG. 9, a diffuser layer 118 can be placed in between outer layer 108 and inner layer 116. The diffuser layer can diffuse the light emitted by the LED chip 104 to scatter the light, or make the light source appear larger than the LED chip 104, or to avoid light hotspots. In an embodiment, the diffuser layer can include light-transmissive small particles or light-reflective small particles. The dispersion can be in silicone or the light transparent/reflective material that can be deposited by thin film deposition techniques. FIGS. 10 and 11 depict similar embodiments as FIGS. 4 and 5, except with the diffuser 118 in place between the outer layer 108 and inner layer 116. The diffuser layer 118 can be placed in this location for improved light dispersion as the light emitted by the LED chip 104 will be more likely to pass through the diffuser layer 118 with a uniform angle (e.g., more perpendicular to the surface of the diffuser layer 118) resulting in more light passing through equal distances of diffuser layer 118 and a more uniform scattering of the light from the LED chip 104.

FIG. 12 is a cross-sectional view of an LED device 100 with a multiple layered cover structure with layers of different refractive indexes and a reflector layer 110 according to aspects disclosed herein

The reflector layer 110 can be placed next to the sides of the LED chip 104 to reduce the side emissions of the LED device 110 and to direct the light and reduce the view angle. In the embodiment shown in FIG. 12, the inner layer 116 can be attached or in contact with the top of the LED chip 104 and the reflector layer 110, and the conversion layer 106 can be in between the inner layer 116 and the outer layer 108. The reflector layer 110 can be any of the light-altering material described above, and in some embodiments can be formed by selectively dispensing material proximate to the LED chip 104.

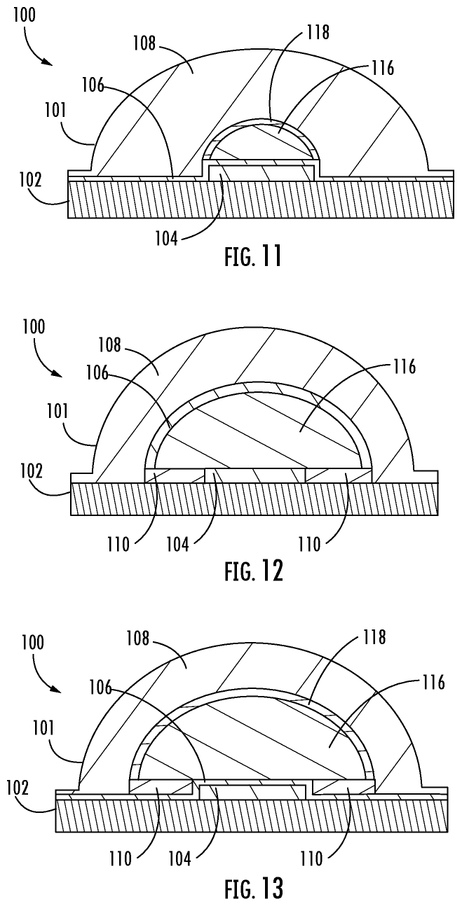

In a similar embodiment in FIG. 13, the conversion layer 106 can be directly in contact with the LED chip 104 and substrate 102, and the reflector layer 110 can be placed around the side of the LED chip 104 next to the conversion layer. The inner layer 116 can be placed on top of the reflector layer 110 and the conversion layer 106, while a diffuser layer 118 can be present between the inner layer 116 and the outer layer 108. In an embodiment, by having the conversion layer 106 extend past the reflector 110 to the edge of the substrate 102, backscattered light reaching the perimeter of the substrate 102 may also be subject to wavelength conversion.

FIG. 14 depicts an embodiment similar to that displayed in FIG. 13, except that in FIG. 14, the reflector layer 110 can be in direct contact with the sides of the LED chip 104, and the conversion 106 can be placed on top of the LED chip 104 and the reflector layer 110. In an embodiment, the reflector 110 can extend to the perimeter edge of the substrate 102.

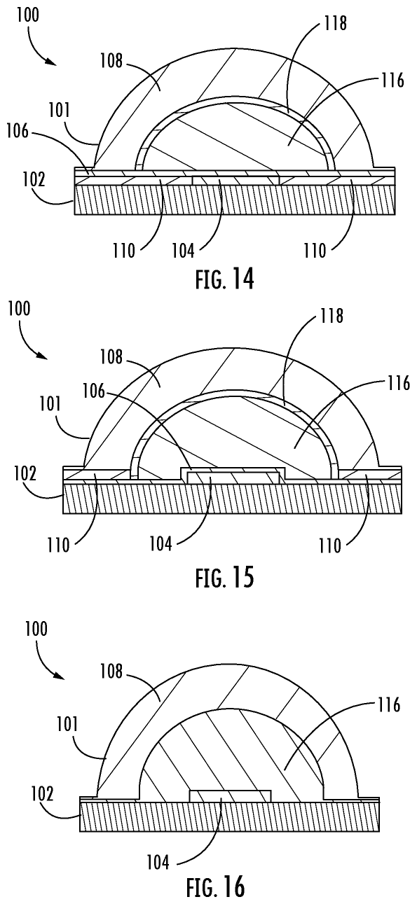

FIG. 15 depicts an embodiment where the conversion layer 106 is placed on top of the LED chip 104, and on the sides of the LED chip 104 and on the surface of the substrate 102, and then the inner layer 116 and diffuser layer 118 is placed on top of the conversion layer 106. The reflector layer 110 can then be on the sides of the diffuser layer 118, with the outer layer 108 covering the diffuser layer 118 and the reflector layer 110.

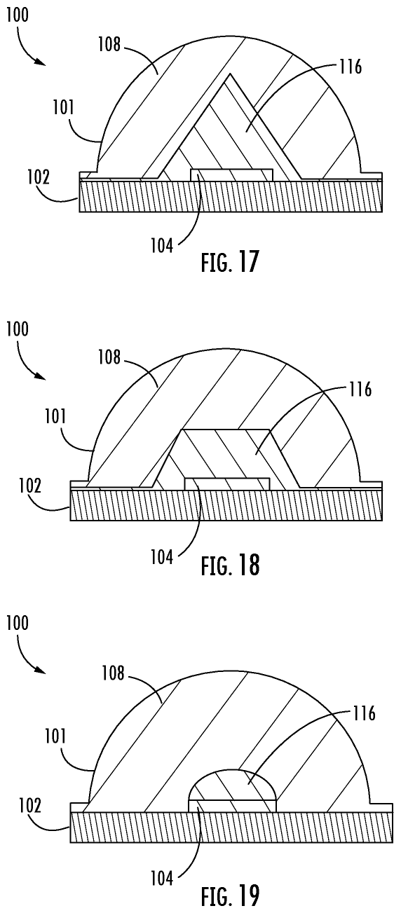

FIG. 16 is a cross-sectional view of an LED device with a multiple layered cover structure with layers of different refractive indexes and embedded lumiphoric material according to aspects disclosed herein. In FIG. 16, the lumiphoric material (e.g., phosphor, etc.) can be embedded in the inner layer 116 as depicted. In other embodiments, the lumiphoric material may be embedded in the outer layer 108. In some embodiments, the inner layer 116 can also include material that can diffuse the light emitted by the LED chip. FIGS. 17, 18, and 19 depict embodiments similar to the embodiments in FIGS. 3, 4, and 5 respectively, except where the lumiphoric material is embedded in the inner layer 116 instead of there being a separate conversion layer 106.

In FIG. 20, the inner layer 116 can include a reflector layer 110 that forms a dam to further block light from emitting out of the side of the LED device 100. The dam of the reflector layer 110 can increase the candela of the LED device 110 and/or narrow the angle of the emission pattern of the light. In the embodiment in FIG. 20, the conversion layer 106 can be between the outer layer 108 and the inner layer 116.

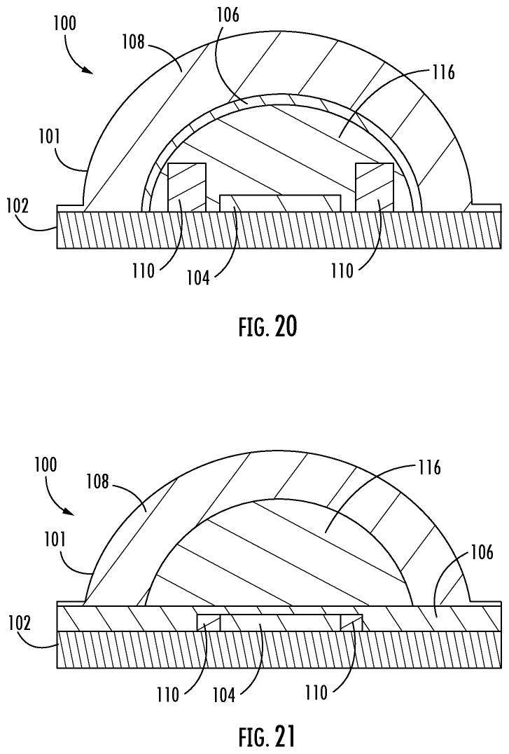

In the embodiment shown in FIG. 21, the LED chip 110 can have reflector layer 110 on the sides of the LED chip 104, and the conversion layer 106 can cover the reflector layer 110 and the LED chip 104. In this embodiment, light reaching the edges of the substrate 102 can be subject to wavelength conversion.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device, comprising:
a substrate;
an LED chip on a top surface of the substrate; and
a cover structure in contact with the substrate that covers a top surface and a side of the LED chip, the cover structure comprising:
an inner layer with a first refractive index, wherein the inner layer covers at least the top surface of the LED chip;
an outer layer with a second refractive index different than the first refractive index, wherein the inner layer is between the LED chip and the outer layer; and
a lumiphoric material.

2. The LED device of claim 1, wherein the inner layer and the outer layer comprise one or more of a silicone material, glass, or a light-transmitting ceramic material.

3. The LED device of claim 1, wherein a difference between the first refractive index and the second refractive index is at least 0.05.

4. The LED device of claim 1, wherein the inner layer and the outer layer are different shapes.

5. The LED device of claim 1, wherein the lumiphoric material forms a conversion layer between the LED chip and the inner layer and outer layer of the cover structure.

6. The LED device of claim 1, wherein the lumiphoric material forms a conversion layer between the inner layer and the outer layer.

7. The LED device of claim 1, wherein the lumiphoric material is embedded in at least one of the inner layer or outer layer.

8. The LED device of claim 7, wherein the inner layer and the outer layer are different shapes.

9. The LED device of claim 1, further comprising a diffuser layer between the inner layer and the outer layer.

10. The LED device of claim 1, further comprising a reflector layer around a sidewall of the LED chip.

11. The LED device of claim 10, wherein the lumiphoric material forms a conversion layer between the sidewall of the LED chip and the reflector layer.

12. The LED device of claim 10, wherein the reflector layer is in contact with the sidewall of the LED chip.

13. The LED device of claim 10, wherein the lumiphoric material forms a conversion layer over the top surface of the LED chip and the reflector layer.

14. The LED device of claim 1, wherein the inner layer and the outer layer are injection molded.

15. The LED device of claim 1, wherein the inner layer covers the side of the LED chip.

16. A light-emitting diode (LED) device, comprising:
a substrate;
an LED chip on a top surface of the substrate; and
a cover structure in contact with the substrate that covers a top surface and a side of the LED chip, the cover structure; comprising:
an inner layer with a first refractive index, wherein the inner layer covers at least the top surface of the LED chip, wherein the inner layer comprises a lumiphoric material; and
an outer layer with a second refractive index different than the first refractive index, wherein the inner layer is between the LED chip and the outer layer.

17. The LED device of claim 16, wherein the inner layer and the outer layer comprise one or more of a silicone material, glass, or a light-transmitting ceramic material.

18. The LED device of claim 16, wherein a difference between the first refractive index and the second refractive index is at least 0.05.

19. The LED device of claim 16, wherein the inner layer and the outer layer are different shapes.

20. The LED device of claim 16, further comprising a diffuser layer between the inner layer and the outer layer.
